(19) United States
(12) Patent Application Publication
(10) Pub. No.: US 2012/0145218 A1
(43) Pub. Date: Jun. 14, 2012

(54) THIN FILM SOLAR CELL MODULE

(76) Inventors: Jeonghun SON, Seoul (KR); Jinhyung JUN, Seoul (KR); Jinhyung AHN, Seoul (KR); Sungeun LEE, Seoul (KR)

(21) Appl. No.: 13/401,232

(22) Filed: Feb. 21, 2012

(30) Foreign Application Priority Data
Feb. 22, 2011 (KR) 10-2011-0015436

(51) Int. Cl. H01L 31/05

(52) U.S. Cl. 136/244

(57) ABSTRACT

A thin film solar cell module includes a substrate, a plurality of solar cells positioned on the substrate, a ribbon electrode positioned on an outermost solar cell of the plurality of solar cells, a plurality of conductive adhesive parts which are positioned between the outermost solar cell and the ribbon electrode and connect the outermost solar cell to the ribbon electrode, a junction box collecting electric power produced by the plurality of solar cells, and a bus bar electrode which is positioned across the plurality of solar cells and connects the junction box to the ribbon electrode. A distance between the plurality of conductive adhesive parts gradually decreases as the plurality of conductive adhesive parts are located closer to the bus bar electrode.

This application claims priority to and the benefit of Korean Patent Application No. 10-2011-0015436 filed in the Korean Intellectual Property Office on Feb. 22, 2011, the entire contents of which are incorporated herein by reference.

### BACKGROUND OF THE INVENTION

1. Field of the Invention

Embodiments of the invention relate to a thin film solar cell module.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts, which respectively have different conductive types, for example, a p-type and an n-type and thus form a p-n junction, and electrodes respectively connected to the semiconductor parts of the different conductive types.

When light is incident on the solar cell, a plurality of electron-hole pairs are produced in the semiconductor parts. The electron-hole pairs are separated into electrons and holes by the photovoltaic effect. The separated electrons move to the n-type semiconductor part, and the separated holes move to the p-type semiconductor part. Then, the electrons and the holes are collected by the electrodes electrically connected to the n-type semiconductor part and the p-type semiconductor part, respectively. The electrodes are connected to each other using electric wires to thereby obtain electric power.

### SUMMARY OF THE INVENTION

In one aspect, there is a thin film solar cell module including a substrate, a plurality of solar cells positioned on the substrate, a ribbon electrode positioned on an outermost solar cell of the plurality of solar cells, a plurality of conductive adhesive parts positioned between the outermost solar cell and the ribbon electrode, the plurality of conductive adhesive parts connecting the outermost solar cell to the ribbon electrode, a junction box configured to collect electric power produced by the plurality of solar cells, and a bus bar electrode positioned across the plurality of solar cells, the bus bar electrode connecting the junction box to the ribbon electrode, wherein a distance between a first and second conductive adhesive parts of the plurality of conductive adhesive parts that are located adjacent to the bus bar electrode is less than a distance between a third and a fourth conductive adhesive parts of the plurality of conductive adhesive parts that are located farther from the bus bar electrode than the first and second conductive adhesive parts.

Lengths of the plurality of conductive adhesive parts may be substantially equal to one another.

A distance between the plurality of conductive adhesive parts may gradually decrease as the plurality of conductive adhesive parts are located closer to the bus bar electrode.

A length of the plurality of conductive adhesive part may increase as the plurality of conductive adhesive parts are located closer to the bus bar electrode.

The plurality of conductive adhesive parts may contain an electrically conductive metal material.

Each of the plurality of solar cells may include a front electrode positioned on the substrate, a back electrode positioned on the front electrode, and a photoelectric conversion unit positioned between the front electrode and the back electrode, the photoelectric conversion unit converting light incident on the photoelectric conversion unit into electricity.

A width of the ribbon electrode may be less than a width of the back electrode of the outermost solar cell.

A width of each of the plurality of conductive adhesive parts may be less than a width of the back electrode of the outermost solar cell.

A width of each of the plurality of conductive adhesive parts may be less than a width of the ribbon electrode.

The thin film solar cell module may further include an insulating part formed between the plurality of solar cells and the bus bar electrode using a non-conductive material. A width of the insulating part may be greater than a width of the bus bar electrode.

In another aspect, there is a thin film solar cell module including a substrate, a plurality of solar cells positioned on the substrate, a ribbon electrode positioned on an outermost solar cell of the plurality of solar cells, a plurality of conductive adhesive parts positioned between the outermost solar cell and the ribbon electrode, the plurality of conductive adhesive parts connecting the outermost solar cell to the ribbon electrode, a junction box configured to collect electric power produced by the plurality of solar cells, and a bus bar electrode positioned across the plurality of solar cells, the bus bar electrode connecting the junction box to the ribbon electrode, wherein a length of a first conductive adhesive part of the plurality of conductive adhesive parts that is located adjacent to the bus bar electrode is greater than a length of a second conductive adhesive part of the plurality of conductive adhesive parts that is located farther from the bus bar electrode than the first conductive adhesive part.

A length of the plurality of conductive adhesive parts may gradually increase as the plurality of conductive adhesive parts are located closer to the bus bar electrode.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIGS. 1 and 2 illustrate a thin film solar cell module according to an example embodiment of the invention;

FIGS. 3 to 5 illustrate in detail a plurality of solar cells that are included in a thin film solar cell module shown in FIG. 1 according to example embodiments of the invention;

FIG. 6 illustrates a configuration of a plurality of conductive adhesive parts according to an example embodiment of the invention; and

FIGS. 7 and 8 illustrate other configurations of a plurality of conductive adhesive parts according to example embodiments of the invention.

### DETAILED DESCRIPTION OF THE EMBODIMENTS

Reference will now be made in detail to embodiments of the invention, examples of which are illustrated in the accompanying drawings. Wherever possible, the same reference numbers will be used throughout the drawings to refer to the same or like parts. Detailed description of known arts will be omitted if it is determined that such description of known arts can mislead one in understanding the embodiments of the invention.

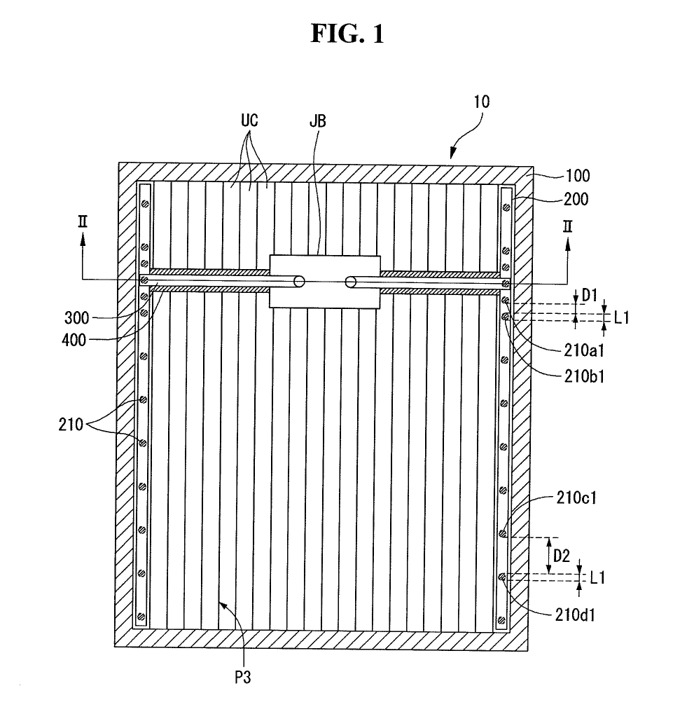

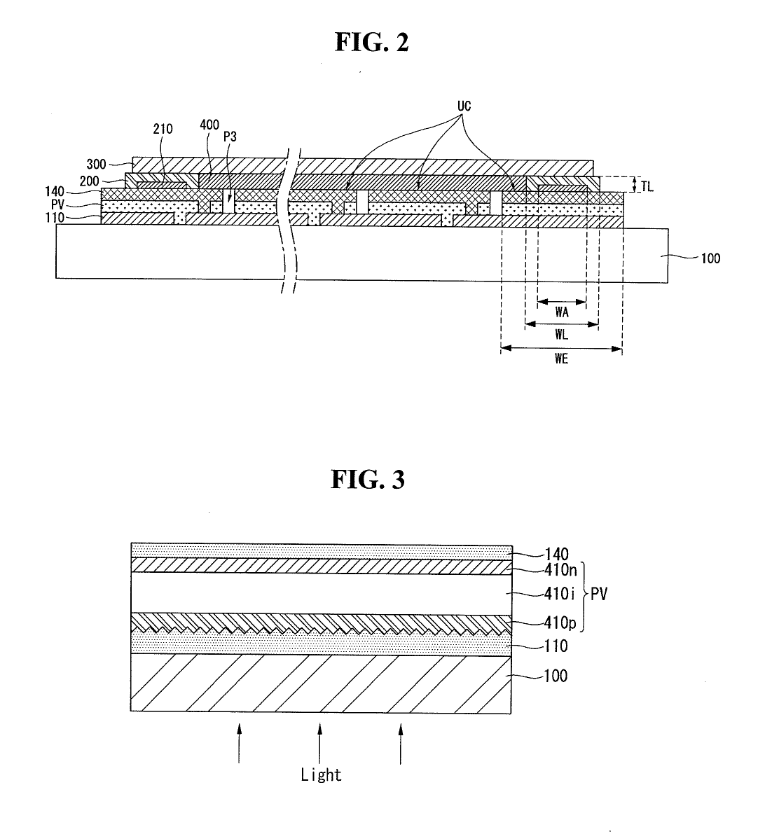

FIGS. 1 and 2 illustrate a thin film solar cell module according to an example embodiment of the invention. More specifically, FIG. 1 is a plane view of a thin film solar cell module according to the example embodiment of the invention, and FIG. 2 is a cross-sectional view taken along line II-II of FIG. 1. A junction box JB shown in FIG. 1 is omitted in FIG. 2 for the sake of brevity.

As shown in FIGS. 1 and 2, a thin film solar cell module 10 according to the embodiment of the invention includes a substrate 100, a plurality of solar cells UC, a ribbon electrode 200, a plurality of conductive adhesive parts 210, a junction box JB, a bus bar electrode 300, and an insulating part 400.

The substrate 100 may provide a space for other functional layers. The substrate 100 may be formed of a substantially transparent material, for example, glass or plastic, so that light incident on the substrate 100 efficiently reaches photoelectric conversion units PV of the solar cells UC.

The plurality of solar cells UC are disposed on the substrate 100. As shown in FIG. 2, each of the plurality of solar cells UC includes a front electrode 110, a back electrode 140, and the photoelectric conversion unit PV.

The front electrode 110 is disposed on the substrate 100, and the back electrode 140 is disposed on the front electrode 110. The photoelectric conversion unit PV is positioned between the front electrode 110 and the back electrode 140 and converts light incident thereon into electricity. Various configurations of individual solar cells are described in detail with reference to FIGS. 3 to 5.

As shown in FIGS. 1 and 2, the plurality of solar cells UC are distinguished from one another using scribing lines P3 shown in a vertical direction of the thin film solar cell module 10.

As shown in FIGS. 1 and 2, the ribbon electrode 200 is disposed on an outermost solar cell UC of the plurality of solar cells UC. More specifically, the ribbon electrode 200 is disposed on the back electrode 140 of the outermost solar cell UC and is electrically connected to the back electrode 140 of the outermost solar cell UC.

The ribbon electrode 200 receives the electricity converted from light from the outermost solar cell UC and transfers the electricity to the bus bar electrode 300 so that the electricity is collected by the junction box JB.

A width WL of the ribbon electrode 200 may be less than a width WE of the back electrode 140 of the outermost solar cell UC. Hence, an electrical short circuit between the ribbon electrode 200 and the back electrode 140 of the solar cell right next to the outermost solar cell UC may be prevented.

The plurality of conductive adhesive parts 210 are formed between the outermost solar cell UC and the ribbon electrode 200 and connect the outermost solar cell UC to the ribbon electrode 200. More specifically, as shown in FIG. 2, the plurality of conductive adhesive parts 210 are formed between the back electrode 140 of the outermost solar cell UC and the ribbon electrode 200 and connect the back electrode 140 of the outermost solar cell UC to the ribbon electrode 200, thereby minimizing a contact resistance between the back electrode 140 of the outermost solar cell UC and the ribbon electrode 200.

The conductive adhesive parts 210 may contain an electrically conductive metal material. For example, the conductive adhesive parts 210 may contain silver (Ag). The metal material such as silver (Ag) has good electrical conductivity and may prevent and/or reduce a damage of the outermost solar cell UC when the conductive adhesive parts 210 are attached to the outermost solar cell UC.

In a method for forming the conductive adhesive parts 210, the metal material, for example, silver (Ag) of a paste form is coated on the back electrode 140 of the outermost solar cell UC at a location to form the conductive adhesive parts 210 at a predetermined distance therebetween.

Next, the ribbon electrode 200 is disposed on the outermost solar cell UC, on which the Ag paste is coated. Heat and pressure are properly applied to the Ag paste to cure the Ag paste. The back electrode 140 of the outermost solar cell UC is electrically connected to the ribbon electrode 200 during the curing of the Ag paste, thereby forming the conductive adhesive parts 210.

The junction box JB collects electric power produced by the plurality of solar cells UC and is connected to the ribbon electrode 200 by the bus bar electrode 300 positioned across the plurality of solar cells UC.

The bus bar electrode 300 is positioned across the plurality of solar cells UC and connects the junction box JB to the ribbon electrode 200.

The insulating part 400 is formed of a non-conductive material and is disposed between the back electrodes 140 of the plurality of solar cells UC and the bus bar electrode 300. The insulating part 400 provides the insulation between the bus bar electrode 300 positioned across the plurality of solar cells UC and the back electrodes 140 of the plurality of solar cells UC.

The insulating part 400 may be formed of synthetic resin material. For example, the insulating part 400 may be formed of ethylene vinyl acetate (EVA), polyvinyl butyral, ethylene vinyl acetate partial oxide, silicon resin, ester-based resin, olefin-based resin, and the like. A width of the insulating part 400 may be greater than a width of the bus bar electrode 300. Further, a thickness of the insulating part 400 may be almost equal to a thickness of the ribbon electrode 200.

In the plurality of conductive adhesive parts 210 according to the embodiment of the invention, a distance D1 between a first conductive adhesive part 210a1 adjacent to the bus bar electrode 300 and a second conductive adhesive part 210b1 right next to the first conductive adhesive part 210a1 is less than a distance D2 between a third conductive adhesive part 210c1 and a fourth conductive adhesive part 210d1 right next to the third conductive adhesive part 210c1. In this instance, the third conductive adhesive part 210c1 is located farther from the bus bar electrode 300 than the first and second conductive adhesive parts 210a1 and 210b1.

In other words, as shown in FIG. 1, the distance D1 between the two adjacent conductive adhesive parts 210a1 and 210b1 adjacent to the bus bar electrode 300 is less than the distance D2 between the two adjacent conductive adhesive parts 210c1 and 210d1 which are farther from the bus bar electrode 300 than the conductive adhesive parts 210a1 and 210b1. In this instance, the two conductive adhesive parts 210a1 and 210b1 positioned adjacent to the bus bar electrode 300 may be separated from each other by the relatively narrow distance D1, and the two conductive adhesive parts 210c1 and 210d1 relatively far from the bus bar electrode 300 may be separated from each other by the relatively wide distance D2 greater than the distance D1.

The distance between the adjacent conductive adhesive parts 210 is determined so as to minimize a contact resistance of a location at which a current is excessively collected due to the bus bar electrode 300.

More specifically, because the junction box JB collects electricity produced by the plurality of solar cells UC, the current is collected from the outermost solar cell UC to the junction box JB via the conductive adhesive parts 210, the ribbon electrode 200, and the bus bar electrode 300. In this instance, the current produced by the plurality of solar cells UC is excessively collected in a portion of the ribbon electrode 200 connected to the bus bar electrode 300. Hence, the current is excessively collected in the conductive adhesive part 210 relatively close to the bus bar electrode 300.

As a result, a contact resistance of the conductive adhesive part 210 relatively close to the bus bar electrode 300 increases, and the efficiency of the thin film solar cell module 10 is reduced.

However, in the embodiment of the invention, the distance between the conductive adhesive parts 210 decreases as the conductive adhesive parts 210 are close to the bus bar electrode 300. Hence, an electrical connection path between the outermost solar cell UC and the ribbon electrode 200 may further widen in a portion of the conductive adhesive part 210 relatively close to the bus bar electrode 300. As a result, a reduction in the efficiency of the thin film solar cell module 10 may be prevented.

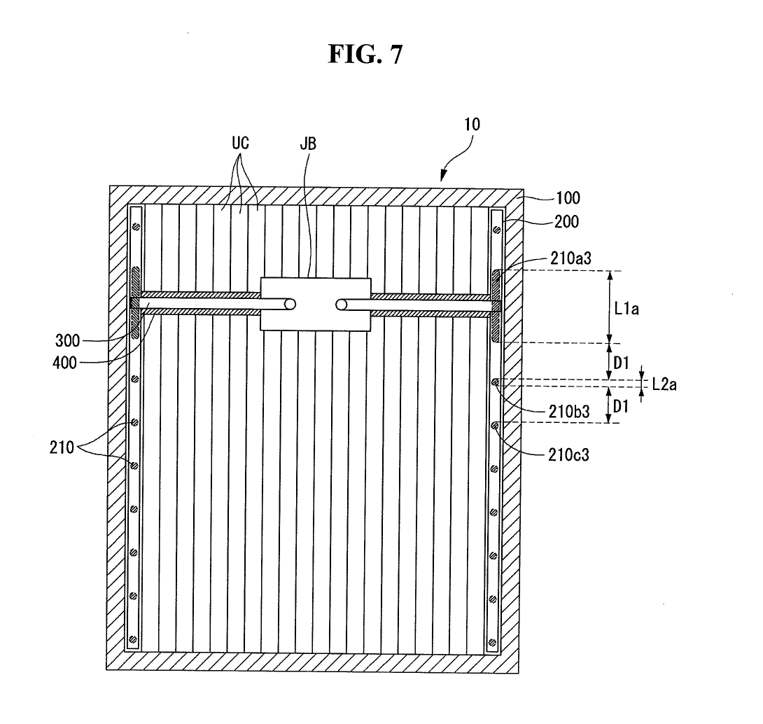

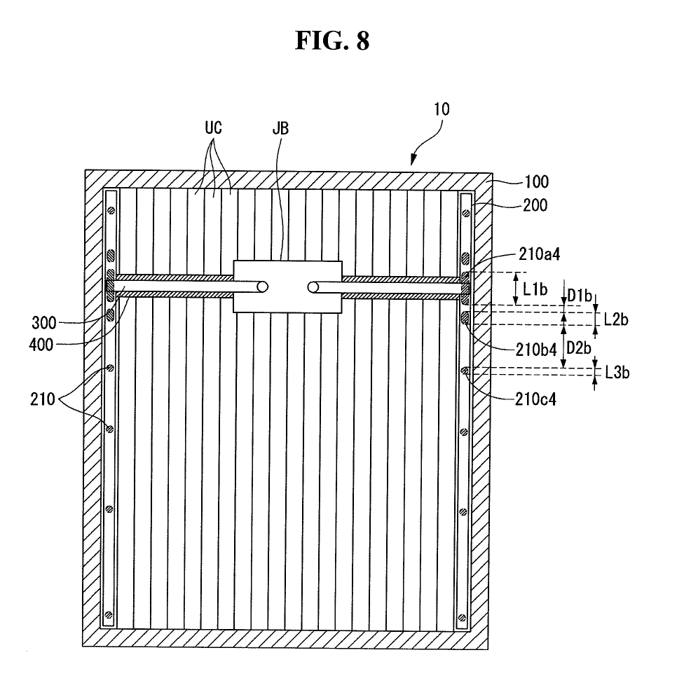

As shown in FIG. 1, lengths L1 of the plurality of conductive adhesive parts 210 may be substantially uniform. Alternatively, the length L1 of the conductive adhesive part 210 may increase in the conductive adhesive parts 210 that are located closer to the bus bar electrode 300. This is described in detail with reference to FIGS. 7 and 8.

As shown in FIG. 2, a width WA of each of the plurality of conductive adhesive parts 210 may be less than the width WE of the back electrode 140 of the outermost solar cell UC. Hence, the electrical short circuit between the conductive adhesive part 210 electrically connected to the back electrode 140 of the outermost solar cell UC and the back electrode 140 of the solar cell right next to the outermost solar cell UC may be prevented.

Further, the width WA of each of the plurality of conductive adhesive parts 210 may be less than the width WL of the ribbon electrode 200. In embodiments of the invention, the lengths L1 of the plurality of conductive adhesive parts 210 extend in a length direction of the ribbon electrode. Also, widths WA of the plurality of conductive adhesive parts 210 are perpendicular to their widths L1. Also, the ribbon electrode 200 envelopes the plurality of conductive adhesive parts 210 against the back electrode 140, whereby some portions of the ribbon electrode 200 directly contacts the back electrode 140, while other portions do not.

FIGS. 3 to 5 illustrate in detail a plurality of solar cells that are included in the thin film solar cell module 10 shown in FIG. 1 according to example embodiments of the invention.

As shown in FIG. 3, the solar cell may have a p-i-n structure in the embodiment of the invention.

FIG. 3 illustrates the photoelectric conversion unit PV having the p-i-n structure based on an incident surface of the substrate 100. Additionally, the photoelectric conversion unit PV may have an n-i-p structure based on the incident surface of the substrate 100. In the following description, the photoelectric conversion unit PV having the p-i-n structure based on the incident surface of the substrate 100 is taken as an example for the sake of brevity.

As shown in FIG. 3, the solar cell may include the substrate 100, the front electrode 110 positioned on the substrate 100, the back electrode 140, and the photoelectric conversion unit PV having the p-i-n structure.

The front electrode 110 is positioned on the substrate 100. The front electrode 110 may contain a substantially transparent material with electrical conductivity so as to increase a transmittance of incident light. More specifically, the front electrode 110 may be formed of a material having high transmittance and high electrical conductivity, so as to transmit most of incident light and allow electricity to flow therein. For example, the front electrode 110 may be formed of at least one selected from the group consisting of indium tin oxide (ITO), tin-based oxide (for example, SnO₂), AgO, ZnO—Ga₂O₃ (or ZnO—Al₂O₃), fluorine tin oxide (FTO), and a combination thereof. A specific resistance of the front electrode 110 may be about 10⁻² Ω·cm to 10⁻¹¹ Ω·cm.

The front electrode 110 may be electrically connected to the photoelectric conversion unit PV. Hence, the front electrode 110 may collect carriers (for example, holes) produced by the incident light and may output the carriers.

A plurality of uneven portions may be formed on an upper surface of the front electrode 110, and the uneven portions may have a non-uniform pyramid structure. In other words, the front electrode 110 may have a textured surface towards the photoelectric conversion unit PV. As described above, when the surface of the front electrode 110 is textured, the front electrode 110 may reduce a reflectance of incident light and increase an absorptance of incident light. Hence, the efficiency of the thin film solar cell module may be improved.

Although FIG. 3 shows only the uneven portions of the front electrode 110, the photoelectric conversion unit PV may have a plurality of uneven portions among various layers and/or surfaces. In the embodiment of the invention, for example, only the uneven portions of the front electrode 110 are described below for the sake of brevity.

The back electrode 140 may be formed of a metal material with good electrical conductivity so as to increase a recovery efficiency of electric power produced by the photoelectric conversion unit PV. The back electrode 140 electrically connected to the photoelectric conversion unit PV may collect carriers (for example, electrons) produced by incident light and may output the carriers.

The photoelectric conversion unit PV is positioned between the front electrode 110 and the back electrode 140 and produces the electric power using light incident thereon from the outside.

The photoelectric conversion unit PV may have the p-i-n structure including a p-type semiconductor layer 410p, an intrinsic (called i-type) semiconductor layer 410i, and an n-type semiconductor layer 410n that are sequentially formed on the incident surface of the substrate 100 in the order named. Other layers may be included or present in the photoelectric conversion unit PV.

The p-type semiconductor layer 410p may be formed using a gas obtained by adding impurities of a group III element, such as boron (B), gallium (Ga), and indium (In), to a raw gas containing silicon (Si).

The i-type semiconductor layer 410i may prevent or reduce a recombination of carriers and may absorb light. The i-type semiconductor layer 410i may absorb incident light to produce carriers such as electrons and holes.

The i-type semiconductor layer 410i may contain microcrystalline silicon (mc-Si), for example, hydrogenated microcrystalline silicon. (mc-Si:H). Alternatively, the i-type semiconductor layer 410i may contain amorphous silicon (a-Si), for example, hydrogenated amorphous silicon (a-Si:H).

The n-type semiconductor layer 410n may be formed using a gas obtained by adding impurities of a group V element, such as phosphorus (P), arsenic (As), and antimony (Sb), to a raw gas containing silicon (Si).

The photoelectric conversion unit PV may be formed using a chemical vapor deposition (CVD) method, such as a plasma enhanced CVD (PECVD) method.

In the photoelectric conversion unit PV, the p-type semiconductor layer 410p and the n-type semiconductor layer 410n may form a p-n junction with the i-type semiconductor layer 410i interposed therebetween. In other words, the i-type semiconductor layer 410i may be positioned between the p-type semiconductor layer 410p (i.e., a p-type doped layer) and the n-type semiconductor layer 410n (i.e., an n-type doped layer).

In such a structure of the solar cell illustrated in FIG. 3, when light is incident on the p-type semiconductor layer 410p, a depletion region is formed inside the i-type semiconductor layer 410i because of the p-type semiconductor layer 410p and the n-type semiconductor layer 410n each having a relatively high doping concentration, thereby generating an electric field. Electrons and holes, which are produced by a photovoltaic effect in the i-type semiconductor layer 410i corresponding to a light absorbing layer are separated from each other by a contact potential difference and move in different directions. For example, the holes may move to the front electrode 110 through the p-type semiconductor layer 410p, and the electrons may move to the back electrode 140 through the n-type semiconductor layer 410n. Hence, the electric power may be produced when the semiconductor layers 410p and 410n are respectively connected using external wires, for example.

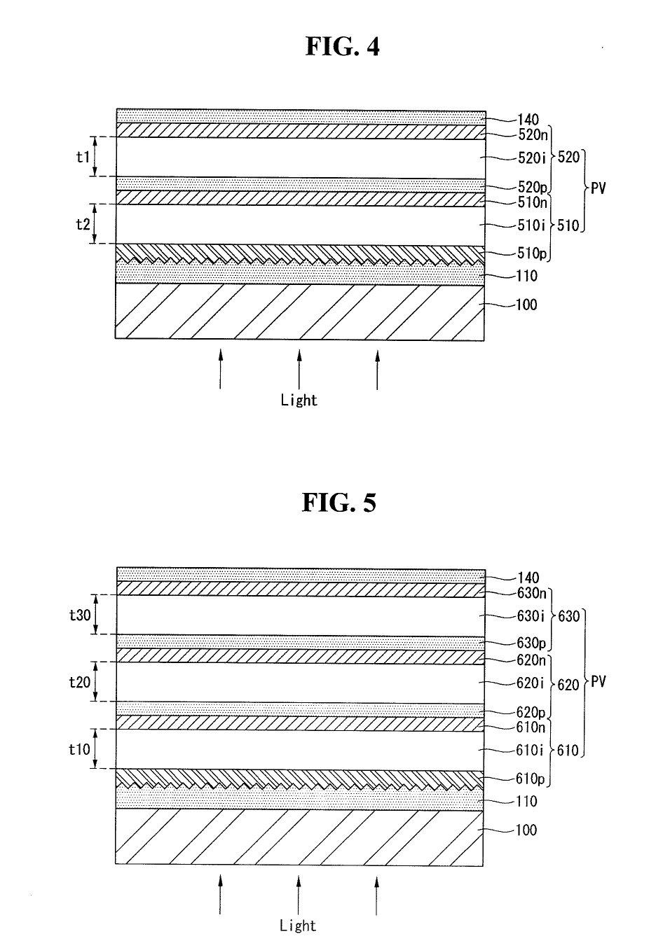

Alternatively, as shown in FIG. 4, the solar cell of the thin film solar cell module according to the embodiment of the invention may have a double junction structure or a p-i-n/p-i-n structure. In the following description, the descriptions of the configuration and the structure described above may be briefly made or may be entirely omitted.

As shown in FIG. 4, the photoelectric conversion unit PV of the double junction solar cell may include a first photoelectric conversion unit 510 and a second photoelectric conversion unit 520.

More specifically, a first p-type semiconductor layer 510p, a first i-type semiconductor layer 510i, a first n-type semiconductor layer 510n, a second p-type semiconductor layer 520p, a second i-type semiconductor layer 520i, and a second n-type semiconductor layer 520n may be sequentially stacked on the incident surface of the substrate 100 in the order named. Other layers may be included or present in the photoelectric conversion unit PV.

The first i-type semiconductor layer 510i may mainly absorb light of a short wavelength band to produce electrons and holes. The second i-type semiconductor layer 520i may mainly absorb light of a long wavelength band to produce electrons and holes.

As described above, because the double junction solar cell absorbs light of the short wavelength band and light of the long wavelength band to produce carriers, the efficiency of the thin film solar cell module can be improved.

A thickness t1 of the second i-type semiconductor layer 520i may be greater than a thickness t2 of the first i-type semiconductor layer 510i, so as to sufficiently absorb light of the long wavelength band.

In the photoelectric conversion unit PV shown in FIG. 4, the first i-type semiconductor layer 510i of the first photoelectric conversion unit 510 and the second i-type semiconductor layer 520i of the second photoelectric conversion unit 520 may contain amorphous silicon. Alternatively, the first i-type semiconductor layer 510i of the first photoelectric conversion unit 510 may contain amorphous silicon, and the second i-type semiconductor layer 520i of the second photoelectric conversion unit 520 may contain microcrystalline silicon.

Further, in the photoelectric conversion unit PV shown in FIG. 4, the second i-type semiconductor layer 520i of the second photoelectric conversion unit 520 may be doped with germanium (Ge) as impurities. Because germanium (Ge) may reduce a band gap of the second i-type semiconductor layer 520i, an absorptance of the second i-type semiconductor layer 520i with respect to light of the long wavelength band may increase. Hence, the efficiency of the thin film solar cell module may be improved.

In other words, in the double junction solar cell, the first i-type semiconductor layer 510i may absorb light of the short wavelength band to provide the photoelectric effect, and the second i-type semiconductor layer 520i may absorb light of the long wavelength band to provide the photoelectric effect. Further, because the band gap of the second i-type semiconductor layer 520i doped with Ge is further reduced, the second i-type semiconductor layer 520i may absorb a large amount of light of the long wavelength band. As a result, the efficiency of the thin film solar cell module may be improved.

The PECVD method may be used to dope the second i-type semiconductor layer 520i with Ge. In the PECVD method, waves of a very high frequency (VHF), a high frequency (HF), or a radio frequency (RF) may be applied to a chamber filled with Ge gas.

In the embodiment of the invention, an amount of Ge contained in the second i-type semiconductor layer 520i may be about 3 to 20 atom %. When the amount of Ge is within the above range, the band gap of the second i-type semiconductor layer 520i may be sufficiently reduced. Hence, the absorptance of the second i-type semiconductor layer 520i with respect to light of the long wavelength band may increase.

Even in this instance, the first i-type semiconductor layer 510i may mainly absorb light of the short wavelength band to produce electrons and holes. The second i-type semiconductor layer 520i may mainly absorb light of the long wavelength band to produce electrons and holes. Further, the thickness t1 of the second i-type semiconductor layer 520i may be greater than the thickness t2 of the first i-type semiconductor layer 510i, so as to sufficiently absorb light of the long wavelength band.

Alternatively, as shown in FIG. 5, the solar cell of the thin film solar cell module according to the embodiment of the invention may have a triple junction structure or a p-i-n/p-i-n/p-i-n structure. In the following description, the descriptions of the configuration and the structure described above may be briefly made or may be entirely omitted.

As shown in FIG. 5, the photoelectric conversion unit PV of the triple junction solar cell may include a first photoelectric conversion unit 610, a second photoelectric conversion unit 620, and a third photoelectric conversion unit 630 that are sequentially positioned on the incident surface of the substrate 100 in the order named. Other layers may be included or present in the first, second and/or third photoelectric conversion units or therebetween.

Each of the first photoelectric conversion unit 610, the second photoelectric conversion unit 620, and the third photoelectric conversion unit 630 may have the p-i-n structure in the embodiment of the invention. A first p-type semiconductor layer 610p, a first i-type semiconductor layer 610i, a first n-type semiconductor layer 610n, a second p-type semiconductor layer 620p, a second i-type semiconductor layer 620i, a second n-type semiconductor layer 620n, a third p-type semiconductor layer 630p, a third i-type semiconductor layer 630i, and a third n-type semiconductor layer 630n may be sequentially positioned on the substrate 100 in the order named. Other layers may be included or present in the first, second, and/or third photoelectric conversion units or therebetween.

The first i-type semiconductor layer 610i, the second i-type semiconductor layer 620i, and the third i-type semiconductor layer 630i may be variously implemented.

As a first example, the first i-type semiconductor layer 610i and the second i-type semiconductor layer 620i may contain amorphous silicon (a-Si), and the third i-type semiconductor layer 630i may contain microcrystalline silicon (mc-Si). A band gap of the second i-type semiconductor layer 620i may be reduced by doping the second i-type semiconductor layer 620i with Ge as impurities.

As a second example, the first i-type semiconductor layer 610i may contain amorphous silicon (a-Si), and the second i-type semiconductor layer 620i and the third i-type semiconductor layer 630i may contain microcrystalline silicon (mc-Si). A band gap of the third i-type semiconductor layer 630i may be reduced by doping the third i-type semiconductor layer 630i with Ge as impurities.

The first photoelectric conversion unit 610 may absorb light of a short wavelength band, thereby producing electric power. The second photoelectric conversion unit 620 may absorb light of a middle wavelength band between a short wavelength band and a long wavelength band, thereby producing electric power. The third photoelectric conversion unit 630 may absorb light of the long wavelength band, thereby producing electric power.

A thickness t30 of the third i-type semiconductor layer 630i may be greater than a thickness t20 of the second i-type semiconductor layer 620i, and the thickness t20 of the second i-type semiconductor layer 620i may be greater than a thickness t10 of the first i-type semiconductor layer 610i.

Because the triple junction solar cell shown in FIG. 5 may absorb light of a wider band range, the production efficiency of the electric power of the thin film solar cell module may be improved.

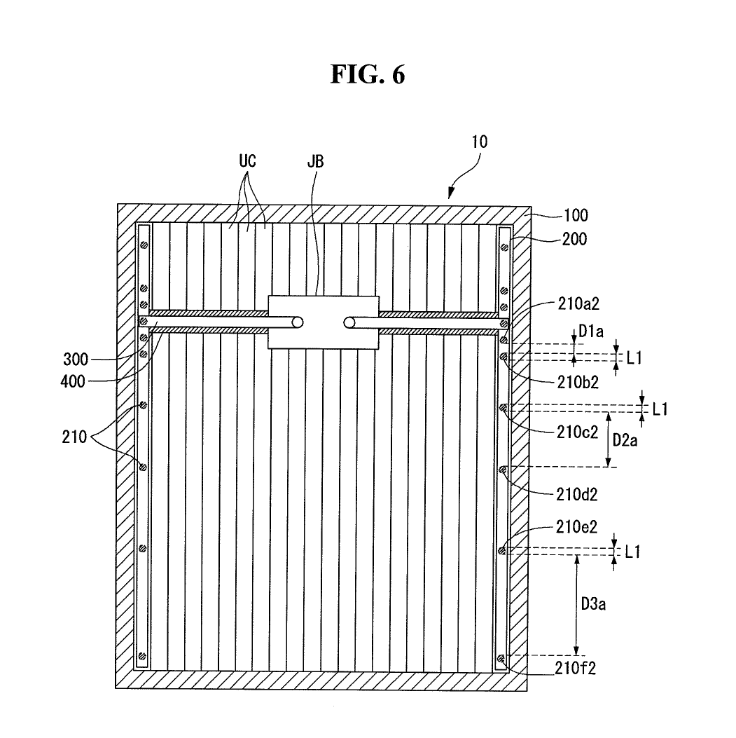

FIG. 6 illustrates another configuration of the conductive adhesive parts 210 according to example embodiments of the invention.

In the conductive adhesive parts 210 shown in FIG. 1, the two conductive adhesive parts 210a1 and 210b1 positioned adjacent to the bus bar electrode 300 are separated from each other by the relatively narrow distance D1, and the two conductive adhesive parts 210c1 and 210d1 relatively far from the bus bar electrode 300 are separated from each other by the relatively wide distance D2.

However, in the conductive adhesive parts 210 shown in FIG. 6, as the conductive adhesive parts 210 are located closer to the bus bar electrode 300, the distances between the conductive adhesive parts 210 gradually decrease. Namely, the distance between the conductive adhesive parts 210 may be proportional to a distance between the conductive adhesive part 210 and the bus bar electrode 300, and thus, may gradually decrease or increase.

More specifically, as shown in FIG. 6, a distance D1 a between two adjacent conductive adhesive parts 210a2 and 210b2 closest to the bus bar electrode 300 may have a minimum value, and a distance D3a between two adjacent conductive adhesive parts 210e2 and 210f2 farthest from the bus bar electrode 300 may have a maximum value. Further, a distance D2a between two adjacent conductive adhesive parts 210c2 and 210d2 positioned between the conductive adhesive parts 210a2 and 210b2 and the conductive adhesive parts 210e2 and 210f2 may be greater than the distance D1a and may be less than the distance D3a.

In the structure of the conductive adhesive parts 210 illustrated in FIG. 6, the contact resistance between the ribbon electrode 200 and the outermost solar cell UC may be reduced by increasing the number of the conductive adhesive parts 210, which are located relatively close to the bus bar electrode 300 and collect a large amount of current. On the contrary, the material used to form the conductive adhesive parts 210 may decrease by reducing the number of the conductive adhesive parts 210, which are located relatively far from the bus bar electrode 300 and collect a small amount of current. Hence, the manufacturing cost of the conductive adhesive parts 210 may be reduced.

So far, the distance between the conductive adhesive parts 210 is controlled (or varied) depending on the distance between the conductive adhesive part 210 and the bus bar electrode 300, so as to reduce the contact resistance between the ribbon electrode 200 and the outermost solar cell UC. In this instance, the lengths L1 of the conductive adhesive parts 210 are substantially uniform. On the other hand, the lengths L1 of the conductive adhesive parts 210 may be controlled (or varied) depending on the distance between the conductive adhesive part 210 and the bus bar electrode 300. This is described in detail with reference to FIGS. 7 and 8.

FIGS. 7 and 8 illustrate other configurations of the conductive adhesive parts 210 according to example embodiments of the invention.

As shown in FIG. 7, in the plurality of conductive adhesive parts 210 according to the embodiment of the invention, a length L1a of a first conductive adhesive part 210a3 adjacent to the bus bar electrode 300 may be greater than a length L2a of a second conductive adhesive part 210b3 which is relatively farther from the bus bar electrode 300 than the first conductive adhesive part 210a3.

More specifically, the length L1a of the conductive adhesive part 210a3 closest to the bus bar electrode 300 may be greater than lengths L2a of conductive adhesive parts 210b3 and 210c3 which are farther from the bus bar electrode 300 than the conductive adhesive part 210a3. In this instance, the distance between the conductive adhesive parts 210 may be substantially uniform.

In the structure of the conductive adhesive parts 210 illustrated in FIG. 7, an increase in the contact resistance resulting from the current excessively collected in the conductive adhesive part 210a3 closest to the bus bar electrode 300 may be prevented. Further, because the lengths L2a of the conductive adhesive parts 210b3 and 210c3 relatively far from the bus bar electrode 300 relatively decrease (or are short), the manufacturing cost of the conductive adhesive parts 210 may be reduced due to less material being used to form the conductive adhesive parts 210b3 and 210c3.

Further, as shown in FIG. 8, the length of the conductive adhesive part 210 may increase based on the degree of closeness or proximity of the conductive adhesive part 210 to the bus bar electrode 300.

More specifically, a length L1b of a conductive adhesive part 210a4 closest to the bus bar electrode 300 may have a maximum value, and a length L2b of a conductive adhesive part 210b4 farther from the bus bar electrode 300 than the conductive adhesive part 210a4 may be less than the length L1b. Further, a length L3b of a conductive adhesive part 210c4 located yet farther from the bus bar electrode 300 than the conductive adhesive part 210b4 may be less than the length L2b.

Further, as the conductive adhesive parts 210 are located closer to the bus bar electrode 300, the distances between the conductive adhesive parts 210 gradually decrease from D2b to D1b in the same manner as the structure of the conductive adhesive parts 210 illustrated in FIG. 6.

In the structure of the conductive adhesive parts 210 illustrated in FIG. 8, an increase in the contact resistance resulting from the current excessively collected in the conductive adhesive part 210a4 closest to the bus bar electrode 300 may be prevented. Further, because the lengths of the conductive adhesive parts 210b4 and 210c4, which are relatively far from the bus bar electrode 300 and reduce the collection of the current, decrease and the distance between the conductive adhesive parts 210b4 and 210c4 increases, the manufacturing cost of the conductive adhesive parts 210 may be reduced.

In FIGS. 7 and 8, the respective conductive adhesive parts 210a3 and 210a4 are disposed directly under the bus bar electrode 300 with the ribbon electrode 200 interposed in between.

In various embodiments of the invention, the conductive adhesive parts 210 may have various shapes, such as a circular shape (e.g., 210a1), an oval shape (e.g., 210b4), and an elongated shape (e.g., 210a3), but the embodiments of the invention are not limited thereto. The conductive adhesive parts 210 may have other polygonal shapes, such as rectangular, triangular, and hexagonal shapes, as well as any other shapes.

In various embodiments of the invention, the arrangement of conductive adhesive parts 210 on opposite sides of the thin film solar cell module 10 may be symmetrical about a middle portion of the thin film solar cell module 10 that bisects the junction box JB, but such is not required.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A thin film solar cell module comprising:
a substrate;
a plurality of solar cells positioned on the substrate;
a ribbon electrode positioned on an outermost solar cell of the plurality of solar cells;
a plurality of conductive adhesive parts positioned between the outermost solar cell and the ribbon electrode, the plurality of conductive adhesive parts connecting the outermost solar cell to the ribbon electrode;
a junction box configured to collect electric power produced by the plurality of solar cells; and
a bus bar electrode positioned across the plurality of solar cells, the bus bar electrode connecting the junction box to the ribbon electrode,
wherein a distance between a first and a second conductive adhesive parts of the plurality of conductive adhesive parts that are located adjacent to the bus bar electrode is less than a distance between a third and a fourth conductive adhesive parts of the plurality of conductive adhesive parts that are located farther from the bus bar electrode than the first and second conductive adhesive parts.

2. The thin film solar cell module of claim 1, wherein lengths of the plurality of conductive adhesive parts are substantially equal to one another.

3. The thin film solar cell module of claim 1, wherein a distance between the plurality of conductive adhesive parts gradually decreases as the plurality of conductive adhesive parts are located closer to the bus bar electrode.

4. The thin film solar cell module of claim 1, wherein a length of the plurality of conductive adhesive part increases as the plurality of conductive adhesive parts are located closer to the bus bar electrode.

5. The thin film solar cell module of claim 1, wherein the plurality of conductive adhesive parts contain an electrically conductive metal material.

6. The thin film solar cell module of claim 1, wherein each of the plurality of solar cells includes:
a front electrode positioned on the substrate;
a back electrode positioned on the front electrode; and
a photoelectric conversion unit positioned between the front electrode and the back electrode, the photoelectric conversion unit converting light incident on the photoelectric conversion unit into electricity.

7. The thin film solar cell module of claim 6, wherein a width of the ribbon electrode is less than a width of the back electrode of the outermost solar cell.

8. The thin film solar cell module of claim 6, wherein a width of each of the plurality of conductive adhesive parts is less than a width of the back electrode of the outermost solar cell.

9. The thin film solar cell module of claim 1, wherein a width of each of the plurality of conductive adhesive parts is less than a width of the ribbon electrode.

10. The thin film solar cell module of claim 1, further comprising an insulating part formed between the plurality of solar cells and the bus bar electrode using a non-conductive material.

11. The thin film solar cell module of claim 10, wherein a width of the insulating part is greater than a width of the bus bar electrode.

12. A thin film solar cell module comprising:
a substrate;
a plurality of solar cells positioned on the substrate;
a ribbon electrode positioned on an outermost solar cell of the plurality of solar cells;
a plurality of conductive adhesive parts positioned between the outermost solar cell and the ribbon electrode, the plurality of conductive adhesive parts connecting the outermost solar cell to the ribbon electrode;
a junction box configured to collect electric power produced by the plurality of solar cells; and
a bus bar electrode positioned across the plurality of solar cells, the bus bar electrode connecting the junction box to the ribbon electrode,
wherein a length of a first conductive adhesive part of the plurality of conductive adhesive parts that is located adjacent to the bus bar electrode is greater than a length of a second conductive adhesive part of the plurality of conductive adhesive parts that is located farther from the bus bar electrode than the first conductive adhesive part.

13. The thin film solar cell module of claim 12, wherein a length of the plurality of conductive adhesive parts gradually increases as the plurality of conductive adhesive parts are located closer to the bus bar electrode.
